(19) United States
(12) Patent Application Publication
(10) Pub. No.: US 2015/0309121 A1
(43) Pub. Date: Oct. 29, 2015

(54) Monitoring IC Chip for Battery Management Unit

(71) Applicant: Stefan Butzmann, Beilstein (DE)

(72) Inventor: Stefan Butzmann, Beilstein (DE)

(73) Assignees: Robert Bosch GmbH, Stuttgart (DE); Samsung SDI Co., Ltd., Yongin-si, Gyeonggi-do (KR)

(21) Appl. No.: 13/993,593

(22) PCT Filed: Nov. 22, 2011
(86) PCT No.: PCT/EP2011/070663

§ 371 Date: Aug. 28, 2013

(30) Foreign Application Priority Data
Dec. 13, 2010 (DE) 10 2010 062 872.7

(51) Int. Cl. G01R 31/36

(52) U.S. Cl. CPC G01R 31/3658; G01R 31/362

(57) ABSTRACT

A monitoring IC chip is designed to detect at least one operating variable from at least one battery cell or from a battery module, which comprises a predetermined number of battery cells, and which can be connected, together with a multiplicity of monitoring IC chips of the same type, to a first bus in a daisy-chain topology such that successive monitoring IC chips in the daisy-chain topology are situated in a rising voltage chain, wherein one of the monitoring IC chips connected to the first bus can be used as a base monitoring IC chip which is designed to use a second bus to communicate with a controller. The monitoring IC chip can be used as the base monitoring IC chip either at a lower end or at an upper end of the voltage chain on the basis of a configuration or an interconnection.

The present invention relates to a monitoring IC chip, a battery management unit having a multiplicity of monitoring IC chips according to the invention, a battery having a battery management unit according to the invention and to a motor vehicle having a battery according to the invention.

### PRIOR ART

It is especially in hybrid and electrical vehicles that batteries in lithium-ion or nickel-metal hydride technology are used today which have a large number of series-connected electrochemical battery cells. A battery management unit is used for monitoring the battery and is intended to guarantee the longest possible life, apart from monitoring safety. For this purpose, the voltage of each individual battery cell is measured together with the battery current and the battery temperature and an estimation of state is performed (for example of the charging state or of the aging state of the battery). In order to maximize the life it helps to know the currently given maximum capacity of the battery, that is to say the maximum electrical power which can be delivered or received, at any time. If this capacity is exceeded, the aging of the battery can be greatly accelerated.

In order to provide for an accurate measurement of the voltage of each individual battery cell or at least of the voltage of each battery module which comprises a predetermined number of battery cells, battery management units are known from the prior art which comprise a multiplicity of series-connected monitoring IC (integrated circuit) chips which can carry out voltage measurements, among other things, and are connected in the form of a daisy chain to an internal bus which provides for communication between the individual monitoring IC chips without requiring DC isolation or the use of high-voltage electronics. In this context, the monitoring IC chips are located with their supply voltages, which are delivered by the battery cells or battery modules to be monitored, in a voltage chain and communicate with one another in such a manner that each monitoring IC chip communicates only with an adjacent monitoring IC chip and passes the communication data which come from monitoring IC chips, which have a higher voltage level, to the monitoring IC chip located in each case lower in the voltage level.

At the end of the communication bus located lowest with regard to the voltage level, a base monitoring IC chip is arranged which is also connected to the first communication bus and which can receive messages from each of the monitoring IC chips. In addition, the base monitoring IC chip is connected by a second bus to a controller which receives the forwarded data via this bus. Between the base monitoring IC chip and the controller, there is usually a DC isolation.

The monitoring IC chips are usually placed in the vicinity of the battery modules allocated to them and the connections for the communication via the first internal bus and the second external bus are implemented by the installation of cable trees.

From the prior art, IC chips are known which can be configured in accordance with the modular concept either as base monitoring IC chip at the lower end of the voltage chain—that is to say with an interface for external communication with the controller and an interface to a further monitoring IC chip in a voltage chain—or also as monitoring IC chip in the daisy chain.

When the concatenation in the daisy chain becomes too long and the data transfer would thus take too long in the communication, the concatenation of the monitoring IC chips must be opened, in which arrangement two or more base monitoring IC chips must be used. The chips known from the prior art can only be positioned as base monitoring IC chips at the lower end of the voltage chain which impedes a flexible arrangement of the chips adapted to the geometry when the concatenation is opened. In particular, the use of long cable trees becomes necessary in particular spatial arrangements.

### DISCLOSURE OF THE INVENTION

According to the invention, a monitoring IC chip (that is to say in the form of an integrated circuit or microchip) is provided which is designed for detecting at least one operating variable of at least one battery cell or one battery module which comprises a predetermined number of battery cells. The monitoring IC chip can be connected, together with a multiplicity of similar monitoring IC chips, to a first bus in a daisy-chain topology in such a manner that successive monitoring IC chips in the daisy-chain topology are located in a rising voltage chain. One of the monitoring IC chips connected to the first bus can be used as base monitoring IC chip which is designed for communicating with a controller via a second bus. The monitoring IC chip can be used as base monitoring IC chip optionally at a lower or at an upper end of the voltage chain in dependence on a configuration or an interconnection.

The invention enables a base monitoring IC chip to be placed at the upper or lower end of a daisy chain concatenation. When two base monitoring IC chips are used, their positioning can be handled more flexibly and, as a result, relatively long cable trees can be avoided depending on the geometric arrangement.

It is possible to provide two communication ports and one of the communication ports can be used optionally for communication with a further similar monitoring IC chip or with a controller in dependence on a configuration or an interconnection.

As an alternative, three communication ports can be provided and one of the communication ports can be used for communication with a controller.

The monitoring IC chip can be used as base monitoring IC chip in a center of the voltage chain.

The monitoring IC chip can be designed for passing messages from a monitoring IC chip adjacent in the voltage chain to another monitoring IC chip adjacent in the voltage chain optionally in the direction of a rising or a falling voltage, in dependence on a configuration or an interconnection.

A further aspect of the invention relates to a battery management unit having a multiplicity of monitoring IC chips according to the invention, wherein each of the monitoring IC chips is connected to a first bus and wherein one of the monitoring IC chips is used as base monitoring IC chip which is also connected to the first bus and is designed for communicating with a controller via a second bus.

Each of the monitoring IC chips can be designed for detecting a voltage of a battery cell or of a battery module.

The base monitoring IC chip can be configured as master at the first bus and each of the monitoring IC chips can be configured as slave at the first bus.

A further aspect of the invention relates to a battery having a multiplicity of series-connected battery cells or battery modules which comprises in each case a predetermined number of battery cells, and having a battery management unit according to the invention. The battery is preferably a lithium-ion battery.

It is possible to provide two daisy chains of monitoring IC chips, wherein one base monitoring IC chip each is connected at one end of each of the daisy chains and wherein one of the two base monitoring IC chips is at a minimum potential of the battery and the other base monitoring IC chip is at a maximum potential of the battery. In this context, the battery cells or the battery modules can be arranged in such a manner that the minimum and the maximum potential are located on one side of the battery.

A further aspect of the invention relates to a motor vehicle, especially an electrical motor vehicle, having a battery according to the invention.

### DRAWINGS

Exemplary embodiments of the invention will be explained in greater detail with reference to the drawings and the subsequent description. In the drawings:

FIG. 1 shows a battery management unit according to the prior art,

FIG. 2 shows a monitoring IC chip according to a first embodiment of the invention,

FIG. 3 shows a monitoring IC chip according to a second embodiment of the invention,

FIGS. 4 and 5 show alternative arrangements of the monitoring IC chips according to the invention in a battery management unit, and

FIG. 6 shows a battery having two separate chains of monitoring IC chips.

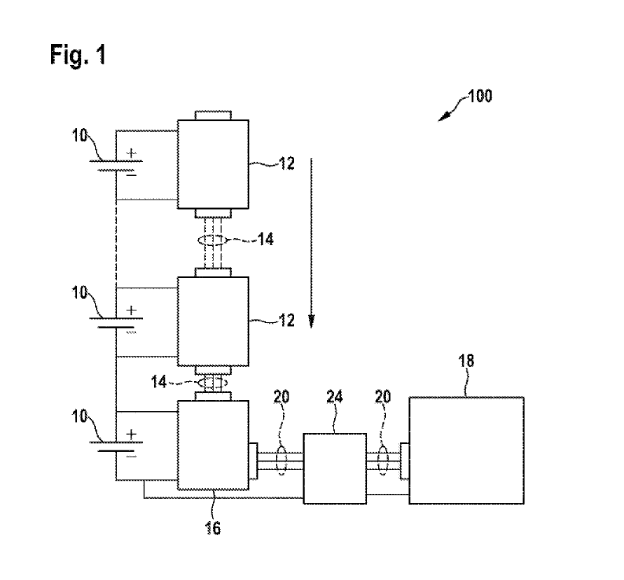

FIG. 1 shows a battery management unit according to the prior art which is a part of a battery designated by 100 overall. The battery management unit comprises a multiplicity of monitoring IC chips 12 which are connected to an internal bus 14 in a daisy-chain topology. Each of the monitoring IC chips 12 is designed for measuring a voltage which is present at an associated battery module 10, a battery module 10 comprising a predetermined number of battery cells, for example 6 to 12 battery cells (only shown diagrammatically in FIG. 1). The battery module 10 can also comprise only one battery cell, in which case the monitoring IC chip 12 allocated to the battery cell measures the individual voltage at the battery cell. The multiplicity of battery modules 10 is connected in series. Each battery module 10 delivers a supply voltage to its associated monitoring IC chip 12 so that the multiplicity of monitoring IC chips 12 is in a rising voltage chain.

Each monitoring IC chip 12 receives data via the internal bus 14 from a monitoring IC chip 12, which may be at a higher level in the voltage chain, and passes the received data, together with data which are generated by itself, to the adjacent monitoring IC chip 12 which is at a lower level in the voltage chain. At the lower end of the voltage chain, a base monitoring IC chip 16 is arranged which receives all data passed through which come from the monitoring IC chips 12 and forwards them via an external bus 20 to which it is connected to a controller 18 which is also connected to the external bus 20 and comprises one or two microcontrollers. Each monitoring IC chip 12 is arranged on its own circuit board which is arranged in the vicinity of the battery module 10 allocated to it.

The internal bus 14 uses a differential protocol which is selected with regard to ruggedness and electromagnetic compatibility in such a manner that the cables of the internal bus 14 can be conducted over a relatively long distance and over a number of circuit boards without the communication on the internal bus 14 being disturbed. In contrast, on the external bus 20, a bus protocol is used which is transmitted single-ended and is optimized for communication with a microcontroller. Such a protocol is more susceptible to interference with regard to electromagnetic compatibility and, in particular, is not designed for being transmitted over a relatively long distance of a cable. Examples of this are an SPI (serial peripheral interface) bus or an I²C (inter-integrated circuit) bus.

A DC isolation unit 24 isolates the base monitoring IC chip 16 and a first part of the external bus 20, on the one hand, and a second part of the external bus 20 and the controller 18, on the other hand, from one another. In the DC isolation unit 24, a voltage supply of the first part of the external bus 20 is also provided.

In the configuration shown in FIG. 1, the base monitoring IC chip 16 can be configured as master at the first bus 14 and each of the monitoring IC chips 12 can be configured as slave.

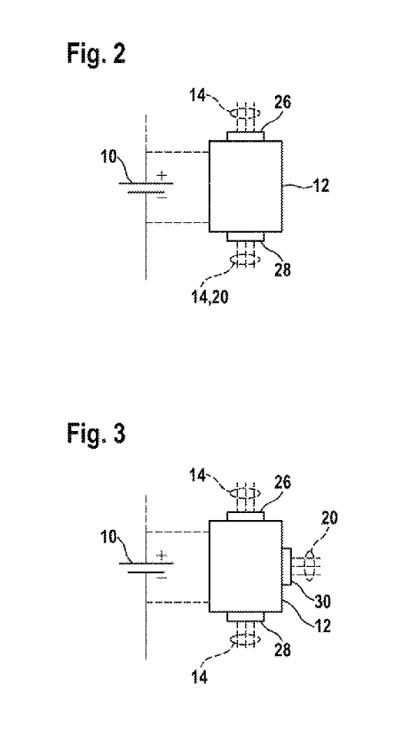

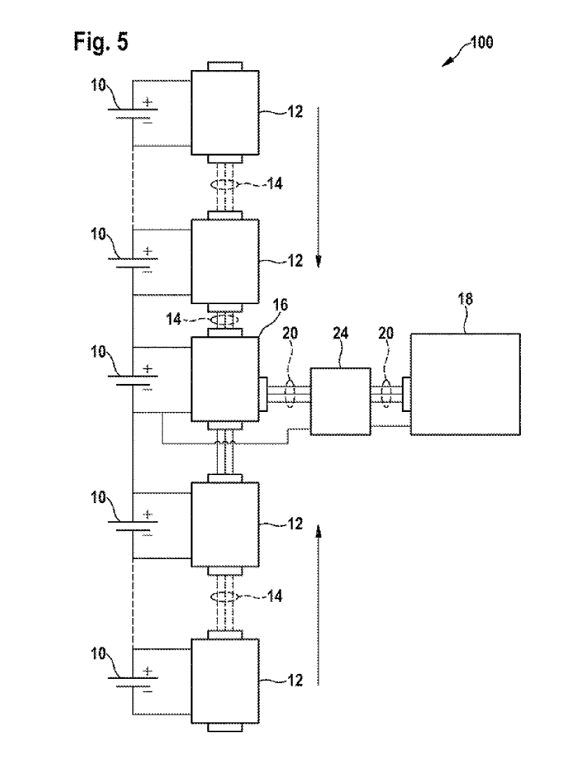

FIG. 2 shows a monitoring IC chip 12 according to a first embodiment of the invention. The monitoring IC chip 12 according to the invention can be used both as base monitoring IC chip 16 and as one of the remaining monitoring IC chips 12 in the arrangement shown in FIG. 1 in accordance with the modular concept. In addition, the monitoring IC chip 12 according to the invention can also be used flexibly in other arrangements, however, which are shown, among other things, in FIGS. 4, 5 and 6. The monitoring IC chip 12 shown in FIG. 2 has a first communication port 26 and a second communication port 28. In the arrangements mentioned, the first communication port 26 is used for communication via the internal bus 14 with an adjacent similar monitoring IC chip 12 which is also connected to the internal bus 14 (shown diagrammatically in FIG. 2). The second communication port 28 can be used optionally for communication with a further similar monitoring IC chip 12 via the internal bus 14 or with a controller 18 via the external bus 20. When the latter is chosen, the monitoring IC chip 12 handles the special function of a base monitoring IC chip 16. According to the invention, it is provided that it is then possible to choose whether it can be used as base monitoring IC chip 16 at a lower end or at an upper end of the voltage chain.

The form of communication and the positioning with respect to the voltage level can be chosen either by configuring the monitoring IC chip 12 to be suitable as a chip, for example by programming, or by suitably interconnecting it. The latter means that the monitoring IC chip 12 can detect the connections to adjacent components or buses. For example, the chip can determine during an initialization which adjacent components or buses are connected to the second communication port 28 and draws from this the conclusion which bus protocol is to be used for communicating via the communication port 28.

The monitoring IC chip 12 is also designed for passing messages from a monitoring IC chip 12 adjacent in the voltage chain to another monitoring IC chip 12 adjacent in the voltage chain optionally in the direction of a rising or of a falling voltage. A monitoring IC chip 12 arranged in the center of the voltage chain thus does not necessarily need to forward communication data in the direction of the minimum potential as is the case in the arrangement shown in FIG. 1 but can also forward it in a reverse direction. Here, too, the direction of communication can be chosen either by the monitoring IC chip 12 being suitably configured as a chip, for example by programming, or due to the fact that it is suitably interconnected and can detect the connections to adjacent components or buses. For example, the chip can determine during an initialization whether the base monitoring IC chip 16, to which communication data are to be sent, is arranged above or below in the voltage chain.

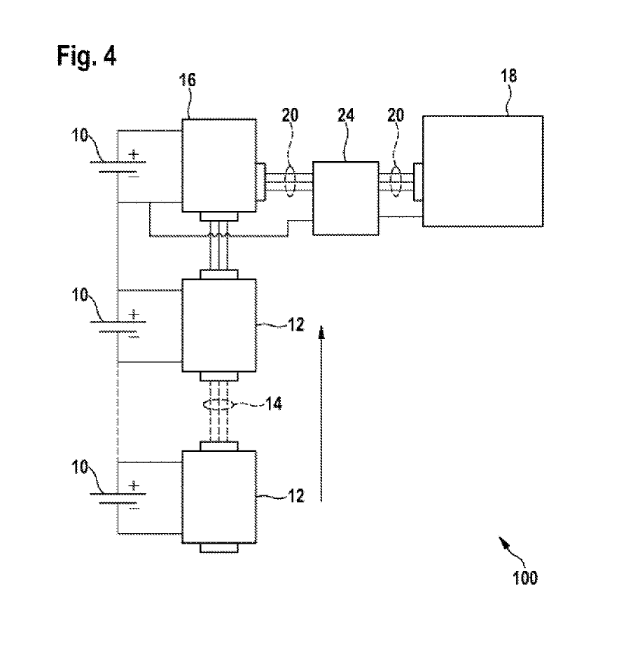

FIG. 3 shows a monitoring IC chip 12 according to a second embodiment of the invention. This differs from the monitoring IC chip 12 shown in FIG. 2 in that it has a third communication port 30 apart from the first two communication ports 26, 28. The two first communication ports 26, 28 are in each case used for communication via the internal bus 14 to an adjacent similar monitoring IC chip 12 which is also connected to the internal bus 14. The third communication port 28, in contrast, is used for communication with a controller 18 via the external bus 20.

Which of the communication ports 26, 28, 30 are used depends on the arrangement of chips selected in the actual case. In most cases, at least one of communication ports 26, 28, 30 will not be assigned so that corresponding pins of the chips remain unused. The assignment of communication ports 26, 28, 30 can be chosen as in the first embodiment of the invention by suitably configuring the individual monitoring IC chip 12, for example by programming, or by suitably interconnecting it.

Analogously to the first embodiment, the monitoring IC chip 12 according to the second embodiment is designed for handling the special function of a base monitoring IC chip 16 at a lower or an upper end of the voltage chain. It is also designed for passing messages from a monitoring IC chip 12 adjacent in the voltage chain to another monitoring IC chip 12 adjacent in the voltage chain, optionally in the direction of a rising or a falling voltage.

Which of the directions is chosen depends again on the arrangement of chips chosen in the actual case.

FIGS. 4 and 5 show arrangements in which the monitoring IC chip 12 according to the invention can be used in accordance with the modular concept in addition to the arrangement shown in FIG. 1.

The arrangement shown in FIG. 4 differs from that shown in FIG. 1 in that the chip used as base monitoring IC chip 16, which receives all data passed through which come from the monitoring IC chips 12 and forwards them to the controller 18 via the external bus 20, is arranged at an upper end of the voltage chain. Each of the remaining monitoring IC chips 12 receives data from a monitoring IC chip 12 possibly located lower in the voltage chain via the internal bus 14 and passes the received data, together with data which are generated by itself, to the adjacent monitoring IC chip 12 which is located higher in the voltage chain.

The arrangement shown in FIG. 5 represents a mixture of the arrangements shown in FIGS. 1 and 4. The chip used as base monitoring IC chip 16 is arranged in a center of the voltage chain. This can be implemented only by a chip according to the second embodiment of the invention since this requires three communication ports. Each of the remaining monitoring IC chips 12 communicates in the direction of a rising or a falling voltage depending on its position in the arrangement as is indicated by arrows in FIG. 5. On average, communication is faster in this arrangement than in the arrangements of FIGS. 1 and 4 since it takes place over fewer chips.

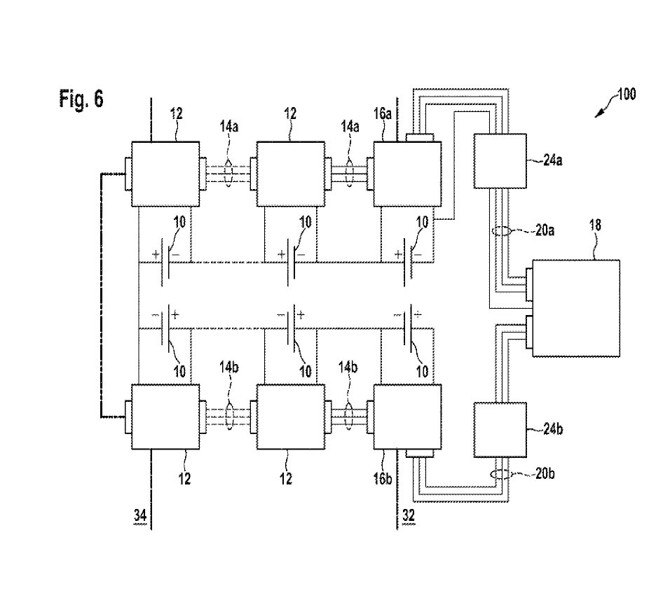

FIG. 6 shows a battery 100 in which the battery modules 10 are connected in series and are arranged in a horseshoe shape in such a manner that the minimum and the maximum potential are located on a first side 32 of the battery on which the controller 18 is also arranged. If only one chain of monitoring IC chips 12 were provided, a part of the associated internal bus would have to be arranged at an opposite second side 34 of the battery (indicated by a dashed line in FIG. 6) which would lead to an increased susceptibility to interference of the bus system. In addition, the data transfer could take too long in communication with a daisy chain extended too far. For this reason, the chaining of the monitoring IC chips 12 is separated and two internal buses 14a, b are arranged in parallel with one another. Two monitoring IC chips according to the invention are used mirror-symmetrically as adjacent base monitoring IC chips 16a, b, both of which are arranged on the first side 32 and one of the two base monitoring IC chips 16a being located at a minimum potential of the battery and the other base monitoring IC chip 16b being located at a maximum potential of the battery. Due to this arrangement of the two base monitoring IC chips 16a, b in the immediate vicinity of the controller 18, the required length of external buses 20a, b which connect the two base monitoring IC chips 16a, b and the controller 18 can be reduced.

1. A monitoring IC chip configured to detect at least one operating variable of at least one battery cell or one battery module having a predetermined number of battery cells, the monitoring IC chip being configured to be connected, together with a plurality of similar monitoring IC chips, to a first bus in a daisy-chain topology such that successive monitoring IC chips in the daisy-chain topology are located in a rising voltage chain, wherein:
the monitoring IC chip is a base monitoring IC chip configured to communicate with a controller via a second bus, and
the base monitoring IC chip is optionally positioned at one of a lower end and an upper end of the voltage chain in dependence on a configuration or an interconnection.

2. The monitoring IC chip as claimed in claim 1, further comprising:
two communication ports,
wherein one of the two communication ports is configured to communicate with one of a further similar monitoring IC chip and the controller in dependence on a configuration or an interconnection.

3. The monitoring IC chip as claimed in claim 1, further comprising:
three communication ports,
wherein one of the three communication ports is configured to communicate with the controller.

4. The monitoring IC chip as claimed in claim 3, wherein the base monitoring IC chip is positioned at a center of the voltage chain.

5. The monitoring IC chip as claimed in claim 1, wherein the monitoring IC chip is configured to pass data from a first adjacent monitoring IC chip in the voltage chain to a second adjacent monitoring IC chip in the voltage chain optionally in a direction of a rising or a falling voltage, in dependence on a configuration or an interconnection.

6. A battery management unit comprising:
a plurality of monitoring IC chips connected together in a daisy-chain topology such that successive monitoring IC chips of the plurality of monitoring IC chips in the daisy-chain topology are located in a rising voltage chain, wherein:
each of the plurality of monitoring IC chips is connected to a first bus, and
one of the plurality of monitoring IC chips is a base monitoring IC chip which is also connected to the first bus and is configured to communicate with a controller via a second bus.

7. The battery management unit as claimed in claim 6, wherein each monitoring IC chip of the plurality of monitoring IC chips is configured to detect a voltage of a battery cell or of a battery module.

8. The battery management unit as claimed in claim 6, wherein:
the base monitoring IC chip is configured as master at the first bus, and
each of the other monitoring IC chips of the plurality of monitoring IC chips is configured as slave at the first bus.

9. A battery comprising:
a multiplicity of series-connected battery cells or battery modules each having a predetermined number of battery cells; and
a battery management unit having a plurality of monitoring IC chips configured to be connected together in a daisy-chain topology such that successive monitoring IC chips of the plurality of monitoring IC chips in the daisy-chain topology are located in a rising voltage chain, wherein:
each of the plurality of monitoring IC chips is configured to detect a voltage in one of the multiplicity of battery cells or battery modules,
each of the plurality of monitoring IC chips is connected to a first bus, and
one of the plurality of monitoring IC chips is a base monitoring IC chip which is also connected to the first bus and is configured to communicate with a controller via a second bus.

10. The battery as claimed in claim 9, wherein:
the plurality of monitoring IC chips includes a first daisy chains of monitoring IC chips and a second daisy chain of monitoring IC chips, wherein:
the first daisy chain includes a first base monitoring IC chip connected at one end of the first daisy chain,
the second daisy chain includes a second base monitoring IC chip connected at one end of the second daisy chain, and
wherein one of the first and second base monitoring IC chips is positioned at a minimum potential of the battery and the other of the first and second base monitoring IC chip is positioned at a maximum potential of the battery.

11. The battery as claimed in claim 10, wherein the battery cells or the battery modules are configured such that the minimum and the maximum potential are located on one side of the battery.

12. A motor vehicle, comprising:
a battery as claimed in claim 11.

13. The motor vehicle of claim 12, wherein the motor vehicle is an electrical motor vehicle.
